(19) United States
(12) Patent Application Publication
(10) Pub. No.: US 2006/0124943 A1
(43) Pub. Date: Jun. 15, 2006

(54) Large-sized light-emitting diodes with improved light extraction efficiency

(75) Inventors: Yun Li Li, Tainan City (TW); Willian Wilson So, Walnut, CA (US); Heng Liu, Sunnyvale, CA (US)

Correspondence Address: MACPHERSON KWOK CHEN & HEID LLP, 1762 TECHNOLOGY DRIVE, SUITE 226, SAN JOSE, CA, 95110, US

(73) Assignee: eLite Optoelectronics Inc., Rowland Heights, CA (US)

(21) Appl. No.: 11/010,512

(22) Filed: Dec. 14, 2004

(51) Int. Cl. H01L 33/00

(52) U.S. Cl. 257/94

(57) ABSTRACT

A light-emitting device with an array of window openings to enhance the light extraction efficiency from this device is provided. This array of window openings is employed to create a much larger sidewall area to enhance the light extraction from the sidewalls of these openings. With this array of window openings, photons trapped due to the total internal reflection can propagate within the device and be extracted from the sidewalls of these openings. A variation of designs can be applied to the array of window openings. Even the shape of these openings can be designed such that the area of the sidewalls is increased. Large-sized light-emitting diodes can improve the light extraction efficiency by employing the array of window openings.

### BACKGROUND OF THE INVENTION

1. Field of the Invention

The present invention relates to semiconductor light-emitting devices, and more particularly, to the improvement of the light extraction from such devices.

2. Description of the Related Art

A light emitting diode (LED) is a forward-biased p-n junction generating photons by spontaneous electron-hole pair recombination. The first practical p-n junction LED was reported by Nathan in 1962. After decades of development, LED technology has been greatly advanced by improved materials qualities, new material systems, and novel structures. Today, for visible long-wavelength LEDs, i.e. red, yellow, orange, and amber LEDs, the emission efficiencies are superior to incandescent lamps. Meanwhile, very efficient green and blue LEDs have also been successfully achieved since the epitaxy technology of III-V nitride materials has been rapidly developed for last several years. The III-V nitride material system is a group of direct-bandgap compound semiconductors composed of group III-A elements in the periodic table and nitrogen. This material system contains aluminum nitride (ALN), gallium nitride (GaN), indium nitride (InN), as well as any of their alloys AlₓIn_{y}Ga_{z}N (1≧x, y, z≧0,x+y+z=1). AlₓIn_{y}Ga_{z}N material system is very suitable for fabricating short-wavelength LEDs (i.e. green, blue and UV LEDs) due to its large bandgap energy. Owing to fast development for the past few years, efficiencies and brightness of AlₓIn_{y}Ga_{z}N based LEDs have been drastically improved. Nichia's 460nm blue LED chips with an output power of 18.8 mW and external quantum efficiency of 34.9% have been realized, along with 400 nm near-UV chips providing 22.0 mw and 35.5% external quantum efficiency.

Due to the success and the great potential of the LED technology, LEDs have become one of the most important light sources for next generation illumination. However, for illuminating applications, it is necessary to enhance the light output per LED chip to reduce the cost, i.e. more lumens per chip are needed. To reach this goal, higher operating current densities or larger sizes are considered.

Unfortunately, when a LED chip is driven with high current density, the chip is heated and the temperature of this chip increases. High temperature can reduce the radiative recombination rate to decrease the internal quantum efficiency of the LED chip and thus the performance is reduced as well.

Another option to increase the light output per LED chip is to increase the size of this chip. However it has been shown that the external quantum efficiencies of LEDs go down when the sizes of LEDs are increased. One of the constraints of sizing up a LED chip is the inability to effectively spread the electric current uniformly over the entire LED. Such effect is known as current crowding. Because of current crowding effect, the electric current could concentrate at certain regions on a LED chip to induce local heating and to cause premature degradation of the device. The current crowding effect can degrade the performance more on large-sized LED chips since the distribution of electric current over large-sized LEDs is much more difficult. Thus, when designing a large-sized LED chip, it is necessary to pay extra attention on how electric currents can be spread uniformly over the device.

Another constraint is the absorption loss of photons within the semiconductor thin film. It is known that total internal reflection of light occurs when light is propagating from media 1 to media 2 and the incident angle of the light beam at the interface is greater than the critical angle. The critical angle is determined by Snell's law, θ_{c}=Sin⁻¹(n₂/n₁), n₁>n₂, where n₁ and n₂ are refractive indices of media 1 and media 2, respectively. A large number of photons emitting from the active region of a LED are total internally reflected at the interface of the semiconductor and air to bounce back and forth within the semiconductor thin films many times due to the high refractive indices of semiconductors as shown in FIG. 1. Thus, the length of the optical paths (the path for a photon to move) of these photons is much longer than the absorption length to increase the chance of the absorption of photons within semiconductor thin films. The loss of photons due to the absorption drastically reduces the performance of large-sized LEDs.

Accordingly, it is an intention to provide an improved LED device, which can reduce the absorption of photons trapped inside.

### SUMMARY OF THE INVENTION

It is one objective of the present invention to provide a light-emitting device employing a design of an array of window openings to create a larger sidewall area within an emitting area thereof to enhance light extraction from this device.

It is another objective of the present invention to provide a large-sized light-emitting diode chip with an array of window openings to efficiently extracting photons trapped inside the large-sized light-emitting diode chip.

In order to attain the above objectives, the present invention provides a light-emitting device, which includes: a light-emitting diode chip having a substrate, an N-type semiconductor layer, a P-type semiconductor layer and a light emitting layer interposed between the N-type semiconductor layer and P-type semiconductor layer; at least one window opening within an emitting area of the light-emitting diode chip; and an N-electrode connected to the N-type semiconductor layer and a P-electrode connected to the P-type semiconductor layer.

The window openings within the emitting area of the light-emitting diode chip increase sidewall areas within the emitting area, and hence reduce the length of optical path before photons can reach the sides of the light-emitting diode chip. The photons traveling inside the light-emitting diode chip can easily escape from the sidewalls of these window openings before they are absorbed. The light extraction efficiency of the light-emitting diode chip is improved.

### BRIEF DESCRIPTION OF THE DRAWINGS

These and other features, aspects and advantages of the present invention will be better understood with regard to the following description, appended claims and accompanying drawings that are provided only for further elaboration without limiting or restricting the present invention, where:

FIG. 1 is a schematic illustration of photons trapped within LEDs due to the total internal reflection;

FIG. 2 is a schematic illustration of three optical paths for photons;

FIG. 3A is a schematic illustration of an optical path of photons by total internal reflection;

FIG. 3B is a schematic illustration of enhancement of light extraction by employing an array of window openings;

FIG. 4A is a schematic top view of a light-emitting device according to a first preferred embodiment of the present invention;

FIG. 4B is a schematic cross-sectional view of FIG. 4A;

FIGS. 4C and 4D are schematic cross-sectional views of two variances of FIG. 4B;

FIG. 5A is a schematic cross-sectional view of a light-emitting device according to a second preferred embodiment of the present invention;

FIGS. 5B and 5C are schematic cross-sectional views of two variances of FIG. 5A;

FIG. 6 is a schematic illustration of different designs of one window opening of the present light-emitting device;

FIG. 7A is a schematic cross-sectional view of a light-emitting device according to a third preferred embodiment of the present invention;

FIG. 7B is a schematic cross-sectional view of a light-emitting device according to a fourth preferred embodiment of the present invention;

FIG. 8A is a schematic top view of a light-emitting device according to a fifth preferred embodiment of the present invention;

FIG. 8B is a schematic front view of FIG. 8A; and

FIGS. 8C and 8D are schematic front views of two variances of FIG. 8B.

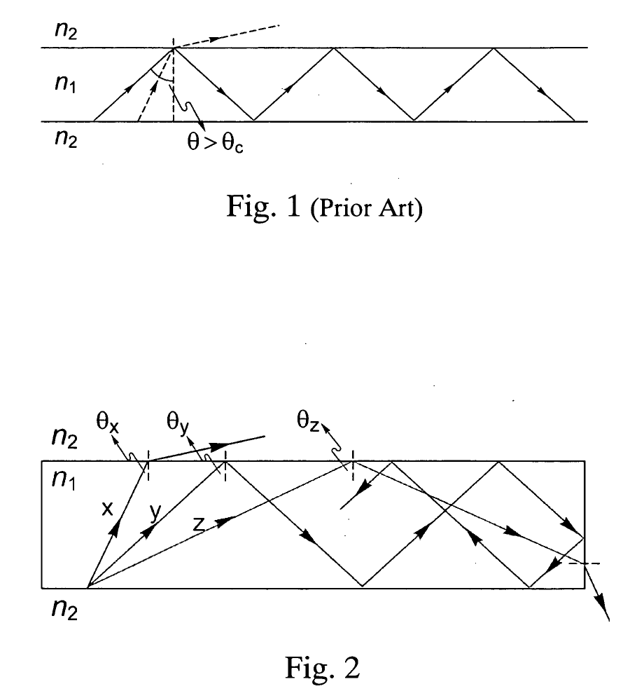

### DETAILED DESCRIPTION OF THE PREFERRED EMBODIMENTS

The present invention is a light-emitting device with an array of window openings to enhance the light extraction efficiency from this device. This array of window openings is employed to create a much larger sidewall area to enhance the light extraction from the sidewall of these openings. With this array of window openings, photons trapped due to the total internal reflection can propagate within the device and be extracted from the sidewall of these openings. It is of great importance for large-sized LEDs to extract photons employing this array of window openings because of the huge loss of photons caused by absorption. These openings are created by etching deep into the epitaxial layer or may be even down to the substrate. A variation of designs can be applied to the array of window openings. The window openings can be etched very rough to enhance the light emission from the sidewall; or reflected mirrors can be fabricated in the windows to redirect photons escaping from the device. Even the shape of these window openings can be designed such that the surface area of the sidewall is increased.

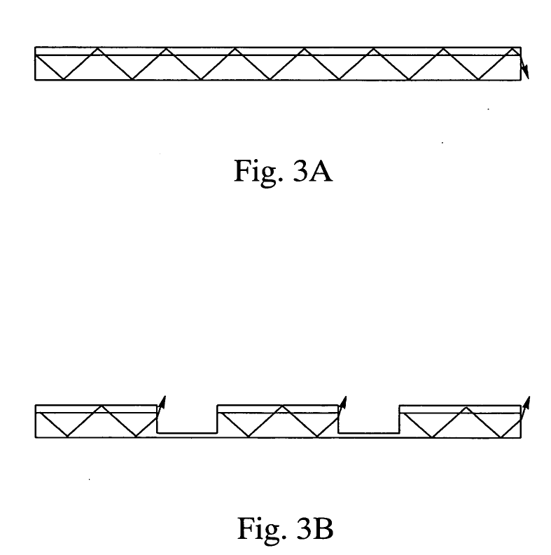

It is known that if the critical angle is smaller than 45°, three types of optical paths could happen in a rectangular shape semiconductor chip as shown in FIG. 2. In FIG. 2, x, y and z are three different light paths with incident angles θₓ, θ_{y} and θ_{z}. θₓ is smaller than the critical angle θ_{c} so that light through x path is diffracted and escapes from top side of the semiconductor chip; light through y and z paths with incident angles (90°−θ_{c})>θ_{y}>θ_{c} and θ_{z}>(90°−θ_{c}) is total internally reflected at top and bottom surfaces to bounce back and forth within the semiconductor chip until it hits the sidewall of the chip. For light through y path, since θ_{y}>(90°−θ_{c} ), the incident angle at the sidewall (90°−θ_{y}) is larger than the critical angle θ_{c} and thus light cannot escape from the sidewall either and is trapped within the chip until it is absorbed. On the other hand, for light through z path, the incident angle at the sidewall (90°−θ_{z}) is smaller than the critical angle θ_{c} to enable light emission from the sidewall.

Due to the high indices of refraction for semiconductors, the critical angles for light propagating from semiconductors into air are usually very small. As shown in Table I, the refractive index of GaN is 2.5 at wavelength λ=410 nm; the refractive index of GaP is 3.3 at λ=590 nm; the refractive index of GaAs is 4.0 at λ=590 nm. The critical angles calculated according to Snell's law are 23.6°, 17.6°, and 14.5°, respectively.

TABLE I

| | Semiconductor material | | |
|---|---|---|---|
| | GaN | GaP | GaAs |
| Index of refraction | 2.5(λ = | 3.3(λ = | 4.0(λ = |
| | 410 nm) | 590 nm) | 590 nm) |
| Critical angle (into air) | 23.6° | 17.6° | 14.5° |

As a result of the small critical angle of these semiconductor materials, it is appropriate to assume that a lot of photons can be extracted from the sidewall of LED chips. Unfortunately, a lot of photons are absorbed on their way to the sidewall and reduce the performance of the LED. The absorption loss becomes more severe when the chip size is getting larger and is one of the key issues to limit the scaling-up of LED chips.

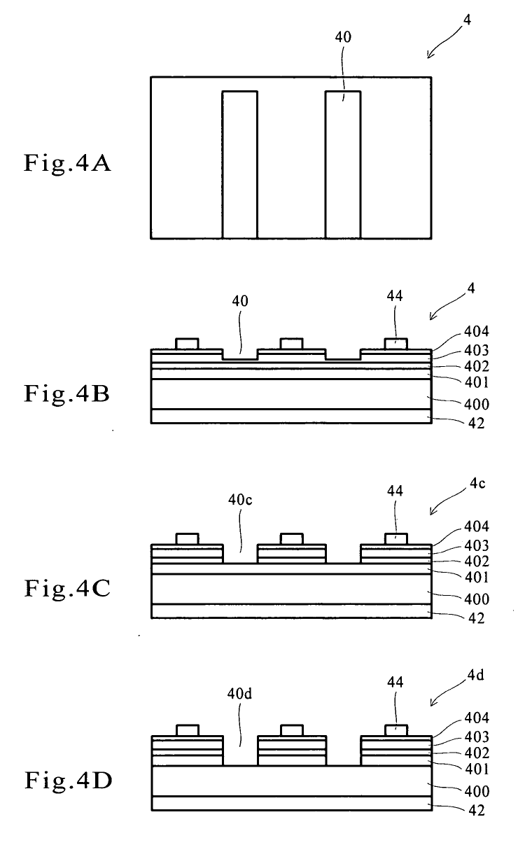

The array of openings created can reduce the length of optical path before photons can reach the sidewall. As shown in FIG. 3A, photons trapped within a large-sized chip need to travel through a long way to reach the sidewall of the chip and can easily be absorbed. But if an array of openings within this chip is generated as shown in FIG. 3B, photons can easily escape from the sidewalls before they are absorbed.

The present invention is a light-emitting device with an array of openings. This array of openings is to enhance the light extraction efficiency of this light-emitting device especially when the device is large-sized (chip size larger than 0.5 mm×0.5 mm). These openings are created by etching deep into the epitaxial layer or may be even down to the substrate. A variation of designs can be applied to the array of windows. The windows can be etched rough to enhance the light emission from the sidewall; or reflected mirrors can be fabricated in the windows to redirect photons escaping from the device. Even the shape of these windows can be designed such that the surface area of the sidewall is increased.

The present invention will be described in detail according to following embodiments with reference to accompanying drawings.

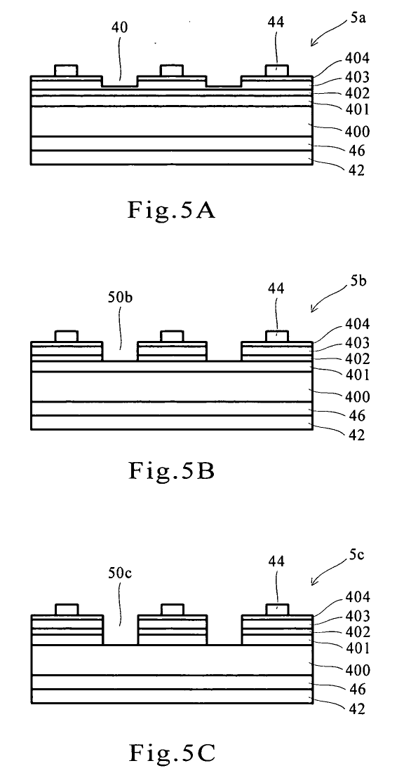

FIGS. 4A and 4B respectively show a schematic top view and schematic cross-sectional view of a light-emitting device 4 according to a first preferred embodiment of the present invention. In FIG. 4A, an N-electrode 42 and a P-electrode 44 are not shown for clarity of the drawing. The light-emitting device 4 includes: a light-emitting diode chip sequentially from bottom to top having a substrate 400, an N-type semiconductor layer 401, a light-emitting layer 402, a P-type semiconductor layer 403 and a current spreading layer 404; an array of window openings 40 formed within an emitting area of the light-emitting diode chip; an N-electrode 42 formed on one bottom surface of the substrate 400; and a P-electrode 44 formed on the current spreading layer 404.

The light-emitting diode chip can be a III-nitride device, and for example, the substrate 400 can be a transparent substrate made of sapphire, the N-type semiconductor layer 401 can be an N-type GaN layer, the light-emitting layer 402 can be a GaN layer and the P-type semiconductor layer 403 can be a P-type GaN layer. The current spreading layer 404 is alternately formed on the P-type semiconductor layer 403 to make the current distribution more evenly on the emitting area, and comprises a transparent conducting oxide layer, such as at least one selected from a group consisting of ITO, CTO, SnO₂:Sb, Ga₂O₃:Sn, NiO, In₂O₃:Zₙ, AglnO₂:Sn, CuAlO₂, LaCuOS, CuGaO₂ and SrCu₂O_{2.}

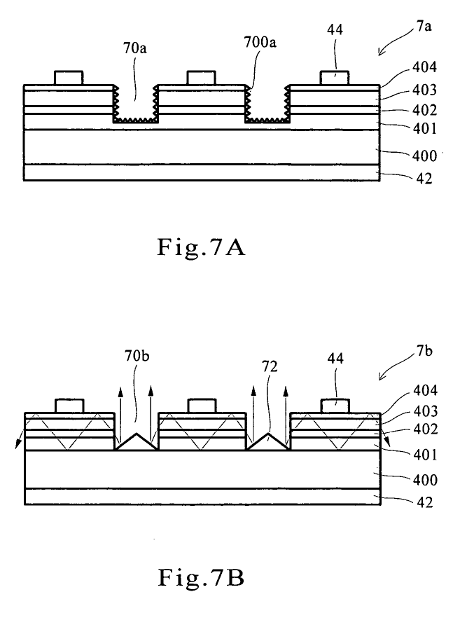

The window openings 40 are deep into the P-type semiconductor layer 403, preferably having a total area less than 50% of the emitting area. Besides, one of the N-electrode 42 and P-electrode 44 preferably surrounds more than 60% of a peripheral length of one of the window openings 40. The shape of the window openings 40 can have different designs to increase the surface area of the sidewalls of the window openings 40. For example, the shape of the widow opening 40 can be polygon, circle, ellipse and irregular. The polygon shape of the window opening 40 can be triangle, square, rectangle, pentagon, hexagon, octagon, trapezoid and parallelogram. FIG. 6 shows illustrations of variances of the window opening 40. FIGS. 4C and 4D show two variances of the light-emitting device 4. In FIG. 4C, the window openings 40c are deep down to the N-type semiconductor layer 401, while remaining parts of the light-emitting device 4c are the same with those of the light-emitting device 4. In FIG. 4D, the window openings 40d are deep down to the substrate 400, while remaining parts of the light-emitting device 4d are the same with those of the light-emitting device 4.

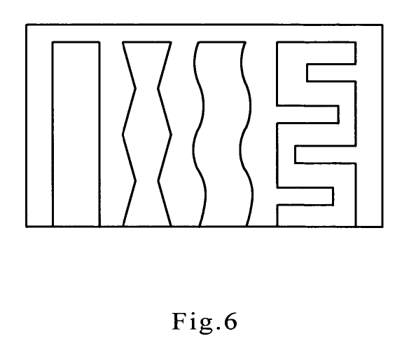

FIG. 5A shows a schematic cross-sectional view of a light-emitting device 5a according to a second preferred embodiment of the present invention. A reflective layer 46 is interposed between the substrate 400 and the N-electrode 42, and the other parts of the light-emitting device 5b are the same with those of the light-emitting device 4. The reflective layer 46 is used to redirect the photons transmitting the substrate 400 back into the emitting area of the light-emitting diode chip. FIGS. 5B and 5c respectively are schematic cross-sectional views of two variances of the light-emitting device 5a. In FIG. 5B, the window openings 50b are deep down to the N-type semiconductor layer 401, while the other parts of the light-emitting device 5b are the same with those of the light-emitting device 5a. In FIG. 5C, the window openings 50c are deep down to the substrate 400, while the other parts of the light-emitting device 5c are the same with those of the light-emitting device 5a.

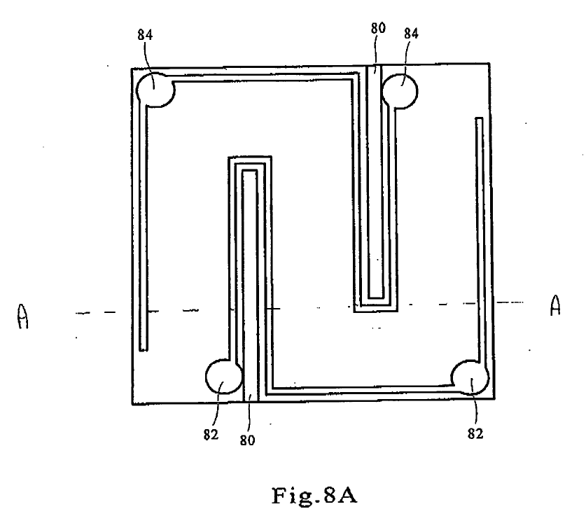

FIG. 7A is a schematic cross-sectional view of a light-emitting device 7a according to a third preferred embodiment of the present invention. In FIG. 7A, sidewalls of the window opening 70a are provided with roughed surfaces 700a to enhance the light emission from the sidewalls. In FIG. 7B, which is a schematic cross-sectional view of a light-emitting device 7b according to a fourth preferred embodiment, a reflector 72 of triangular prism shape is provided in each of the window openings 70b to redirect the light deflected from the sidewalls upward.

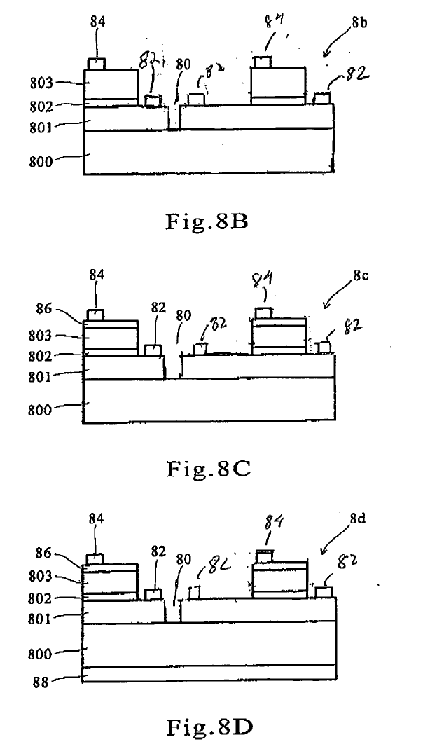

FIGS. 8A and 8B respectively show a schematic top view and a schematic front view of a light-emitting device 8b according to a fifth preferred embodiment of the present invention. The light-emitting device 8b includes a light-emitting diode chip, an N-electrode 82 and a P-electrode 84. Both of the N-electrode 82 and P-electrode 84 are formed on a same side of the light-emitting diode chip, and more than 80% of the N-electrode 82 and P-electrode 84 are equal distance (see FIG. 8A) such that the current flows more evenly in the emitting area of the light-emitting diode chip, and the current crowding effect is eliminated. The light-emitting diode chip sequentially from bottom to top includes a substrate 800, an N-semiconductor layer 801, a light-emitting layer 802 and a P-type semiconductor layer 803, as well as at least two window openings 80 are formed in an emitting area of the light-emitting diode chip. The P-electrode 84 is connected to the P-type semiconductor layer 803 and the N-electrode 82 is connected to the N-type semiconductor layer 801. It should be noted that the materials of various layers of the light-emitting diode chip are the same with those of the light-emitting diode chip of FIG. 4B.

FIGS. 8C and 8D respectively show schematic front views of two variances of the light-emitting device 8b. In FIG. 8C, a current spreading layer 86 is formed on the P-type semiconductor layer 803 to make the current distribution more evenly on the emitting area, and comprises a transparent conducting oxide layer, such as at least one selected from a group consisting of ITO, CTO, SnO₂:Sb, Ga₂O₃:Sn, NiO, In₂O₃:Zₙ, AglnO₂:Sn, CuAl0₂, LaCuOS, CuGaO₂ and SrCu₂O₂. In FIG. 8D, except for the current spreading layer 86 formed on the P-type semiconductor layer 803, a reflective layer 88 is formed on a bottom surface of the substrate 800 to redirect the photons transmitting from the substrate 800 back into the emitting area.

In accordance with the present light-emitting device with an array of window openings, an applied current density of the present device is in the range from 25A/cm² to 100A/cm^{2.}

Although the present invention has been described in considerable detail with reference to certain preferred embodiments thereof, those skilled in the art can easily understand that all kinds of alterations and changes can be made within the spirit and scope of the appended claims. Therefore, the spirit and scope of the appended claims should not be limited to the description of the preferred embodiments contained herein.

1. A light-emitting diode, comprising:
a substrate;
an N-type semiconductor layer;
a P-type semiconductor layer;
a light emitting layer interposed between said N-type semiconductor layer and said P-type semiconductor layer;
at least one window opening with an emitting area of said light-emitting diode, the at least one window opening extending at least partially through the P-type semiconductor layer; and
an N-electrode connected to said N-type semiconductor layer and a P-electrode connected to said P-type semiconductor layer.

2. The light-emitting diode as defined in claim 1, wherein said at least one window opening extends through the P-type semiconductor layer and through the N-type semiconductor layer

3. The light-emitting diode as defined in claim 1, wherein a said at least one opening window is selected from a group consisting of polygon, circle, ellipse, and irregular.

4. The light-emitting diode as defined in claim 3, wherein said polygon is selected from the group consisting of triangle, square, rectangle, pentagon, hexagon, octagon, trapezoid, and parallelogram.

5. The light-emitting diode as defined in claim 1, wherein a total area of said at least one window opening is less than 50% of said emitting area.

6. The light-emitting diode as defined in claim 1, wherein surfaces of said at least one window opening is roughed.

7. The light-emitting diode as defined in claim 1, further comprising a reflector with a shape of a triangular prism within said at least one window opening.

8. The light-emitting diode as defined in claim 1, further comprising a current spreading layer formed on said P-type semiconductor layer.

9. The light-emitting diode as defined in claim 8, wherein said current spreading layer comprises a transparent conducting oxide layer.

10. The light-emitting diode as defined in claim 9, wherein said transparent conducting oxide layer is selected from a group consisting of ITO, CTO, SnO₂:Sb, Ga₂O₃:Sₙ, NiO, In₂O₃:Zₙ, AglnO₂:Sn, CuAl:O₂, LaCuOS, CuGaO_{2,} and SrCu₂O_{2.}

11. The light-emitting diode as defined in claim 1, wherein said substrate is a transparent substrate.

12. The light-emitting diode as defined in claim 11, further comprising a reflective layer on a bottom surface of said transparent surface.

13. The light-emitting diode as defined in claim 1, wherein more than 80% of said N-electrode and said P-electrode are separated by an equal distance.

14. The light-emitting diode as defined in claim 1, wherein one of said N-electrode and said P-electrode surrounds more than 60% of a peripheral length of said at least one window opening.

15. The light-emitting diode as defined in claim 1, wherein said light-emitting diode is a III-nitride device.

16. The light-emitting diode as defined in claim 1, wherein said N-electrode and said P-electrode are formed on a same side of said light-emitting diode chip.

17. The light-emitting diode as defined in claim 1, wherein said N-electrode and said P-electrode are formed on opposite sides of said light-emitting diode.

18. The light-emitting diode as defined in claim 1, wherein a size of said light-emitting diode chip is not less than 0.5 mm×0.5 mm.

19. The light-emitting diode as defined in claim 16, wherein more than 80% of said N-electrode and said P-electrode are separated by an equal distance.

20. The light-emitting diode as defined in claim 1, wherein an applied current density of said device is in the range of 25A/cm² and 100A/cm².
